(19) United States
(12) Patent Application Publication
(10) Pub. No.: US 2025/0207715 A1
(43) Pub. Date: Jun. 26, 2025

(54) METHODS AND APPARATUS FOR INSULATING GAS LINES

(71) Applicant: ASM IP Holding B.V., Almere (NL)

(72) Inventors: Kyle Fondurulia, Phoenix, AZ (US); Ankit Kimtee, Phoenix, AZ (US); Hannelore Azora Hemminger, Tempe, AZ (US); Sudhanshu Biyani, Tempe, AZ (US); Ruslan Akhmedagaev, Scottsdale, AZ (US)

(21) Appl. No.: 18/985,210

(22) Filed: Dec. 18, 2024

Related U.S. Application Data
(60) Provisional application No. 63/614,400, filed on Dec. 22, 2023.

(51) Int. Cl. F16L 59/06; F16L 53/34

(52) U.S. Cl. CPC F16L 59/06; F16L 53/34

(57) ABSTRACT

Various embodiments of the present technology may provide an apparatus for vapor delivery system. The vapor delivery system may include a heating element and an insulating layer surrounding a gas line. The insulating layer may have air gaps and may be formed from polyetheretherketone.

### CROSS-REFERENCE TO RELATED APPLICATIONS

This application is a nonprovisional of, and claims priority to and the benefit of, U.S. Provisional Patent Application No. 63/614,400, filed Dec. 22, 2023 and entitled “METHODS AND APPARATUS FOR INSULATING GAS LINES,” which is hereby incorporated by reference herein.

### FIELD OF INVENTION

The present disclosure generally relates to a method and apparatus for insulating gas lines. More particularly, the present disclosure relates to a gas line with a flexible heater affixed to the gas line and an insulating layer having air gaps, in contact with the flexible heater.

### BACKGROUND OF THE TECHNOLOGY

Some reaction chambers used in semiconductor manufacturing utilize a gas distribution plate (sometimes referred to as a showerhead) to deliver various gases, such as a precursor and a reactant, to a substrate and form a film on the substrate. Conventional gas distribution plates provide the precursor and reactant in sequence through a shared set of through-holes in the gas distribution plate. In some cases, it may be advantageous to deliver the precursor and reactant into the reaction chamber through separate plenums.

### SUMMARY OF THE INVENTION

Various embodiments of the present technology may provide a vapor delivery system. The vapor delivery system may include a heating element and an insulating layer surrounding a gas line. The insulating layer may have air gaps and may be formed from polyetheretherketone.

According to one aspect, a vapor delivery system comprises: a gas line comprising a sidewall comprising an interior surface and an opposing exterior surface; a metal layer surrounding the gas line and comprising an outward-facing surface; a heating element comprising a first surface affixed directly to the outward-facing surface of the metal layer, and an opposing second surface; and an insulting layer adjacent to the heating element, wherein the insulating layer comprises a plurality of air gaps.

In one embodiment, the insulating layer comprises a triply periodic minimal surface structure.

In one embodiment, the triply periodic minimal surface structure is a gyroid structure.

In one embodiment, the insulating layer is in direct contact with the heating element.

In one embodiment, the heating element is a flexible heating element.

In one embodiment, the vapor delivery system further comprises a plurality of spacers disposed between the second surface of the heating element and the insulating layer.

In one embodiment, the plurality of spacers are formed from silicon and have a thickness in a range of 1 mm to 3 mm.

In one embodiment, the metal layer comprises aluminum.

In one embodiment, the insulating layer is formed from polyetheretherketone.

In another aspect, a vapor delivery system comprises: a gas line comprising a sidewall comprising an interior surface and an opposing exterior surface; a metal layer, formed from aluminum, surrounding the gas line and comprising an outward-facing surface; a flexible heating element comprising a first surface affixed directly to the outward-facing surface of the metal layer, and an opposing second surface; an insulting layer adjacent to the heating element; and an air gap between the heating element and the insulating layer.

In one embodiment, the vapor delivery system further comprises a plurality of spacers disposed between the second surface of the heating element and the insulating layer.

In one embodiment, the plurality of spacers are formed from silicon and have a thickness in a range of 1 mm to 3 mm.

In one embodiment, the insulating layer comprises fiberglass and has a thickness in a range of 5 mm to 8 mm.

In one embodiment, the insulating layer comprises a triply periodic minimal surface structure and is formed from polyetheretherketone.

In yet another aspect, an apparatus configured to surround a gas line comprises: a metal layer surrounding the gas line; a heating element affixed directly to the metal layer; a plurality of spacers disposed on the heating element, wherein the spacers have a thickness in a range of 1 mm to 3 mm; an insulating layer adjacent to the heating element and in direct contact with the spacers; and an air gap separating the heating element and the insulating layer.

In one embodiment, the plurality of spacers are formed from silicon.

In one embodiment, the insulating layer comprises fiberglass and has a thickness in a range of 5 mm to 8 mm.

In one embodiment, the insulating layer comprises a triply periodic minimal surface structure and is formed from polyetheretherketone.

In one embodiment, the metal layer comprises aluminum.

In one embodiment, the air gap is 1 mm to 3 mm.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a first cross sectional view of a vapor delivery system in accordance with embodiments of the present technology;

FIG. 3 is a second cross sectional view of a vapor delivery system in accordance with embodiments of the present technology; and

FIG. 4 is a perspective view of a gyroid structure in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, pressure controllers, reaction chambers, vessels, and temperature sensors.

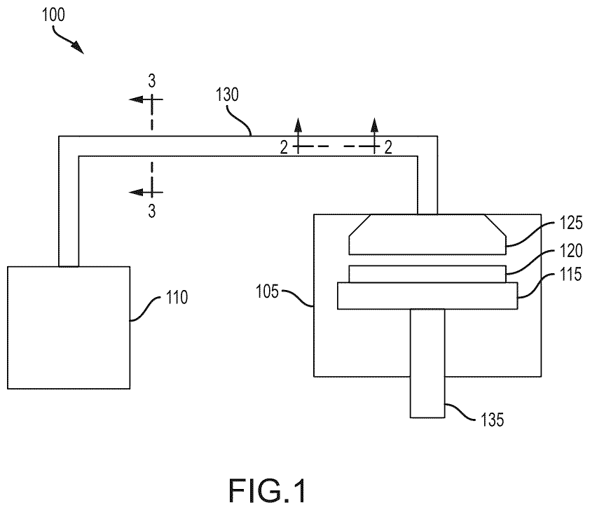

Referring to FIG. 1, an exemplary system 100 may comprise a reactor 105 configured to perform processing on an object to be processed, such as a substrate 120 (e.g., a wafer). For example, the reactor 105 may be configured to perform heating, deposition, etching, polishing, ion implantation, and/or other processing on the object to be processed. In some embodiments, the reactor 105 may be configured to perform a movement function, a vacuum sealing function, a heating function, an exhaust function, and/or other functions for the object to be processed such that the object is processed in the reactor. In some embodiments, the reactor 105 may be a reactor in which an atomic layer deposition (ALD) or a chemical vapor deposition (CVD) process is performed.

In various embodiments, the system 100 may further comprise a substrate mounting unit disposed within the reactor 105. The substrate mounting unit may comprise a susceptor 115 for supporting the substrate 120 and a heater (not shown) for heating the substrate supported by the susceptor 115. The heater may be embedded within the susceptor 115. The substrate mounting unit may further comprise a pedestal 135 to support the susceptor 115. For loading/unloading of the substrate, the substrate mounting unit may be configured to be vertically movable by being connected to a driving unit (not shown).

In various embodiments, the system 100 may further comprise a gas distribution system 125 (i.e., a showerhead) for delivering a vapor into the reactor 105. In an exemplary embodiment, the gas distribution system 125 is arranged above the susceptor 115.

In various embodiments, the system 100 may further comprise a delivery system 130 configured to deliver a gas or vapor from a vessel 110 to the reactor 105. For example, the delivery system 130 may be coupled to the vessel 110 at a first end and the reactor 105 at a second end. The vessel 110 may be configured to contain a solid or liquid chemical that is transformed into a vapor.

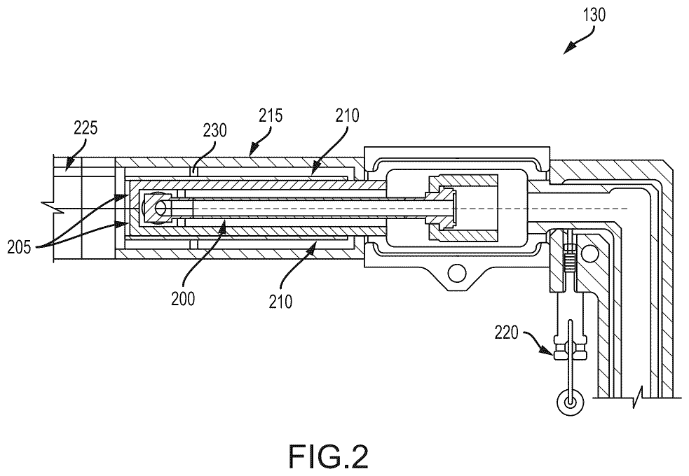

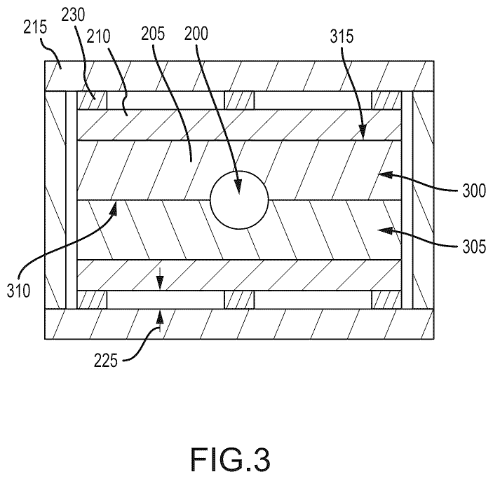

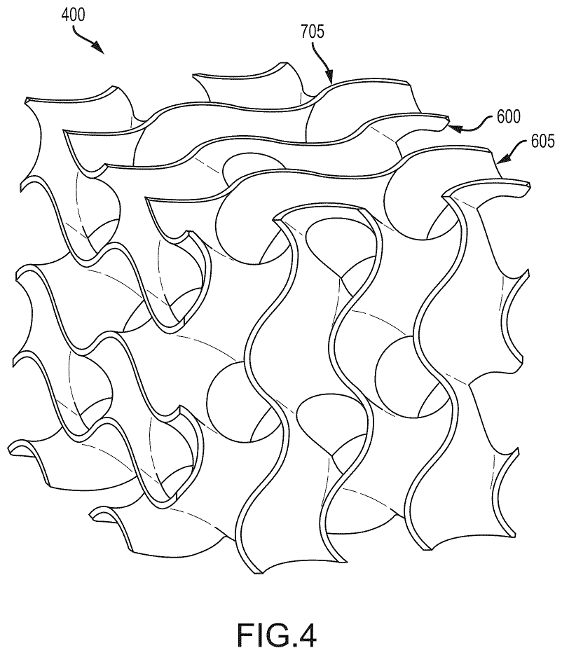

In various embodiments, and referring to FIGS. 2-4, the delivery system 130 may comprise a gas line 200. The gas line 200 may be configured to facilitate flow of a vapor. The gas line 200 may be formed from a metal such as stainless steel or any other suitable metal, and may be any suitable size. For example, the gas line 200 may have a diameter in the range of 0.25 inches to 1 inch. In various embodiments, the gas line 200 may comprise any number of connectors and gas line sections coupled by the connectors. In addition, the delivery system 130 may comprise any number of valves to control the flow and/or pressure of the vapor in the delivery system 130.

In various embodiments, the delivery system 130 may further comprise a metal layer 205 configured to surround the gas line 200. For example, in an exemplary embodiment, the metal layer 205 comprises a first section 300 and a second section 305 that wraps around the gas line 200 and directly contacts the gas line 200. For example, the first and second sections 300, 305 may comprise a cut-out that corresponds to the size and shape of the gas line 200, such that the first and second sections 300, 305 mate with the gas line 200. In addition, the first and second sections 300, 305 may directly contact each other at a seam 310 formed by edges of the first and second sections 300, 305. The metal layer 205 may be formed from a thermally conductive metal, such as aluminum.

In various embodiments, the delivery system 130 may further comprise a heating element 210 configure to heat the metal layer 205 and the gas line 200. For example, the heating element 210 may be affixed to an outward-facing surface of the 315 of the metal layer 205. In various embodiments, the heating element 210 may comprise a resistive heating element or any other suitable type of heating element. The heating element may be affixed to the metal layer 205 with an adhesive. In some embodiments, the heating element 210 may completely surround the metal layer 205. In other embodiments, the heating element 210 may be affixed only to a portion of the outward-facing surface of the metal layer 205. In various embodiments, the heating element 210 may be a flexible heating element. For example, the heating element 210 may be formed from a flexible material, such as a thermoplastic or any other suitable flexible heat resistant material.

In various embodiments, the delivery system 130 may further comprise a plurality of spacers 230 configured to form an air gap 225. The plurality of spacers 230 may be affixed to or otherwise disposed on the heating element 210. In some cases, the plurality of spacers 230 may be integrated with the heating element 210. For example, the plurality of spacers 230 may be formed or affixed to a surface of the heating element 210 that is opposite the side affixed or adhered to the metal layer 205. The plurality of spacers 230 may be formed from silicon and may have a thickness in a range of 1 mm to 3 mm.

In various embodiments, the delivery system 130 may further comprise an insulating layer 215 adjacent to the heating element 210. In some embodiments, the insulating layer 215 may be disposed on the plurality of spacers 230. In this case, the air gap 225 is formed between the heating element 210 and the insulating layer 215. In other embodiments that do not include the plurality of spacers 230, the insulating layer 215 may be in direct contact with the heating element 210. In various embodiments, the insulating layer 215 may surround the heating elements 210 and the metal layer 205 to provide a thermal barrier for the heating element 210 and the metal layer 205. In some embodiments, the insulating layer 215 may comprise a fiberglass material.

In other embodiments, the insulating layer 215 may comprise a thermoplastic material, such as polyetheretherketone (PEEK).

In various embodiments, the insulating layer 215 may comprise a plurality of air pockets. For example, the insulating layer 215 may comprise a 3D lattice structure 400 comprising a first plenum 600 and a second plenum 605. The 3D lattice structure may be a triply period minimal surface structure, for example a gyroid structure or any other structure having two or more separate plenums.

A continuous interior wall 705 separates the first plenum 600 from the second plenum 605. In other words, the first plenum 600 is isolated from the second plenum 605 by the continuous interior wall 705. The insulating layer 215 may further comprise an outer surface wall (not shown) that encloses or otherwise bounds the first and second plenums 600, 605.

In various embodiments, the first plenum 600 may comprise a first plurality of continuous interconnected channels 601 forming the first volume. The first plurality of channels 601 may be branched (i.e., non-linear), for example, two or more channels 601 may connect at a first node. Similarly, the second plenum 605 may comprise a second plurality of continuous interconnected channels 606 forming the second volume. The second plurality of channels 606 may be branched, for example, two or more channels 606 may connect at a second node.

In various embodiments, the first plurality of channels 600 are intertwined with the second plurality of channels 606.

In various embodiments, the insulating layer 215 may be formed from a thermoplastic material by additive manufacturing (i.e., 3D printing) or any other suitable method.

In various embodiments, and referring to FIGS. 1 and 2, the system 100 may further comprise a temperature sensor 220, such as a thermocouple, configured to measure a temperature of the delivery system 130, and in particular, the gas line 200. For example, the temperature sensor 220 may be affixed directly to an outer surface of the gas line 200 or to the metal layer 205. In other cases, the temperature sensor 220 may be embedded within the metal layer 205. The temperature sensor 220 may generate a signal that corresponds to a temperature of the gas line 200.

In various embodiments, the system 100 may also comprise a controller (not shown) configured to control valves (not shown) disposed within the delivery system 130. The controller may operate the valves to facilitate flow of a vapor from the vessel 110 to the reactor 105 according to a desired pulsing scheme. In various embodiments, the controller may control the temperature of the heating elements 210 according to a measured temperature of the gas line 200. For example, the controller may receive the signal from the temperature sensor and may then increase or decrease the temperature of the heating element 210 according to a desired temperature of the gas line 200.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. A vapor delivery system, comprising:
a gas line comprising a sidewall comprising an interior surface and an opposing exterior surface;
a metal layer surrounding the gas line and comprising an outward-facing surface;
a heating element comprising a first surface affixed directly to the outward-facing surface of the metal layer, and an opposing second surface; and
an insulting layer adjacent to the heating element, wherein the insulating layer comprises a plurality of air gaps.

2. The vapor delivery system according to claim 1, wherein the insulating layer comprises a triply periodic minimal surface structure.

3. The vapor delivery system according to claim 1, wherein the triply periodic minimal surface structure is a gyroid structure.

4. The vapor delivery system according to claim 1, wherein the insulating layer is in direct contact with the heating element.

5. The vapor delivery system according to claim 1, wherein the heating element is a flexible heating element.

6. The vapor delivery system according to claim 1, further comprising a plurality of spacers disposed between the second surface of the heating element and the insulating layer.

7. The vapor delivery system according to claim 6, wherein the plurality of spacers are formed from silicon and have a thickness in a range of 1 mm to 3 mm.

8. The vapor delivery system according to claim 1, wherein the metal layer comprises aluminum.

9. The vapor delivery system according to claim 1, wherein the insulating layer is formed from polyetheretherketone.

10. A vapor delivery system, comprising:
a gas line comprising a sidewall comprising an interior surface and an opposing exterior surface;
a metal layer, formed from aluminum, surrounding the gas line and comprising an outward-facing surface;
a flexible heating element comprising a first surface affixed directly to the outward-facing surface of the metal layer, and an opposing second surface;
an insulting layer adjacent to the heating element; and
an air gap between the heating element and the insulating layer.

11. The vapor delivery system according to claim 10, further comprising a plurality of spacers disposed between the second surface of the heating element and the insulating layer.

12. The vapor delivery system according to claim 10, wherein the plurality of spacers are formed from silicon and have a thickness in a range of 1 mm to 3 mm.

13. The vapor delivery system according to claim 10, wherein the insulating layer comprises fiberglass and has a thickness in a range of 5 mm to 8 mm.

14. The vapor delivery system according to claim 10, wherein the insulating layer comprises a triply periodic minimal surface structure and is formed from polyetheretherketone.

15. An apparatus configured to surround a gas line, comprising:
a metal layer surrounding the gas line;
a heating element affixed directly to the metal layer;
a plurality of spacers disposed on the heating element, wherein the spacers have a thickness in a range of 1 mm to 3 mm;
an insulating layer adjacent to the heating element and in direct contact with the spacers; and
an air gap separating the heating element and the insulating layer.

16. The apparatus according to claim 15, wherein the plurality of spacers are formed from silicon.

17. The apparatus according to claim 15, wherein the insulating layer comprises fiberglass and has a thickness in a range of 5 mm to 8 mm.

18. The apparatus according to claim 15, wherein the insulating layer comprises a triply periodic minimal surface structure and is formed from polyetheretherketone.

19. The apparatus according to claim 15, wherein the metal layer comprises aluminum.

20. The apparatus according to claim 15, wherein the air gap is 1 mm to 3 mm.
